(19) United States
(12) Patent Application Publication
(10) Pub. No.: US 2009/0194673 A1
(43) Pub. Date: Aug. 6, 2009

(54) Image detection apparatus

(75) Inventor: Takashi SHOJI, Kanagawa (JP)

Correspondence Address: Moss & Burke, PLLC, 401 Holland Lane, Suite 407, Alexandria, VA, 22314, US

(73) Assignee: FUJIFILM CORPORATION, Minato-ku (JP)

(21) Appl. No.: 12/320,721

(22) Filed: Feb. 3, 2009

(30) Foreign Application Priority Data
Feb. 5, 2008 (JP) 2008-025216

(51) Int. Cl. H03F 3/08; H01L 27/00

(52) U.S. Cl. 250/214 A; 250/208.1

(57) ABSTRACT

An image detection apparatus is provided. The apparatus includes: a conversion unit that converts an emitted radiation ray to an electric charge; a group of pixel units, each of the pixel units including a storage capacitor that stores an electric charge and a switching component connected to the storage capacitor; a plurality of data lines that respectively connect the switching components of the pixel units to first input terminals of a signal detection components so that, when a switching component is turned on, the storage capacitor connected thereto conducts to an input terminal of the signal detection components connected thereto; and a plurality of storage capacitor lines that are separate from each other and that connect the storage capacitors of the pixel units of the pixel group to second input terminals of the signal detection components corresponding to the respective pixel units.

### CROSS-REFERENCE TO RELATED APPLICATION

This application claims priority under 35 USC 119 from Japanese Patent Application No. 2008-025216, the disclosure of which is incorporated by reference herein.

### BACKGROUND OF THE INVENTION

1. Field of the invention

The present invention relates to an image detection apparatus. In particular, the present invention relates to an image detection apparatus that converts an applied radiation or electromagnetic wave to electric charges to store the electric charges for each pixel.

2. Description of the Related Art

In a radiation imaging technology for a medical diagnosis, a system that acquires a digital radiation image has been known. The system applies a radiation having passed through a subject to a radiation detection device provided with a photoelectric conversion layer sensitive to the radiation, reads electric charges, which are stored in the radiation detection device according to the quantity of radiation applied to the radiation detection device, as an electric current for a unit region of reading, and converts the read electric current to digital data. Moreover, a radiation detection panel (direct conversion type radiation detection panel) has been also known as a radiation detection device. The radiation detection panel is configured by forming a photoelectric conversion layer on a TFT active matrix substrate. The TFT active matrix substrate is made by forming a number of TFTs (Thin Film Transistors) and a number of signal wiring on a glass substrate (see, for example, JP-A No. 2001-257333).

A radiation detection panel 130 of a positive bias direct conversion type, as shown in FIG. 8 by way of example, includes a TFT active matrix substrate 140 having a number of pixel units 138 arranged in the shape of a matrix. Each of the pixel unit 138 includes: an electrode 132; a TFT 134 having a drain connected to the electrode 132 and having a gate connected to gate wiring 148; and a storage capacitor 136 having one end connected to the electrode 132. The TFT active matrix substrate 140 has a photoelectric conversion layer 142, the main component of which is amorphous selenium (a-Se), formed thereon. Moreover, the sources of the TFTs 134 of the individual pixel units 138 are connected respectively to the input terminals of amplifiers 150 via data wiring 144, and the other ends of the storage capacitors 136 of the individual pixel units 138 are connected to each other on the substrate 140 or outside the substrate 140 via storage capacitor wiring 146, and the storage capacitor wiring 146 are connected respectively to the input terminals of the individual amplifiers 150.

In this regard, by way of example, FIG. 9 shows the configuration of a typical example of the arrangement of the storage capacitor wiring in a radiation detection panel in a related art. In this configuration, a number of storage capacitor wiring are formed parallel to the gate wiring, and these storage capacitor wiring are connected to each other via connection wiring formed outside an image region on the radiation detection panel, and this connection wiring is connected to a printed substrate via a TCP (Tape Carrier Package) and is held at a reference potential.

A positive bias voltage is applied to the photoelectric conversion layer 142. When a radiation is applied to the radiation detection panel 130, electric charges of magnitude responsive to the quantity of applied radiation are generated at the photoelectric conversion layer 142. The produced electric charges are stored in the storage capacitors 136 via the electrodes 132 of the individual pixel units 138. Moreover, when a control signal for turning on the TFT 134 is inputted to the gate of the TFT 134 via control signal wiring 148, the TFT 134 is turned on and hence the electric charges stored in the storage capacitor 136 are inputted to the amplifier 150 as an electric current. A signal responsive to the quantity of stored electric charges, that is, the quantity of applied radiation is outputted from the amplifier 150. Here, the signal outputted from the amplifier 150 is converted to digital data by an A/D converter.

In this regard, the above-mentioned radiation detection panel is configured so as to convert the applied radiation directly to the electric charges by the photoelectric conversion layer (direct conversion type). However, in addition to this configuration, a configuration, in which an applied radiation is once converted to an electromagnetic wave (for example, visible light or the like) and the converted electromagnetic wave is then converted to electric charges, (indirect conversion type) has been also known.

Generally, in a radiation detection panel, the quantity of electric charges stored in the storage capacitor of each of the pixel units is small, and data wiring formed on a glass substrate has higher electric resistance than signal wiring formed on a printed substrate. For this reason, a signal current flowing through the data wiring at the time of reading the electric charges is small (for example, as small as pA (pico-ampere) level) and noises are easily superimposed on the signal current. Accordingly, the S/N ratio of the signal current at the time of reading the electric charges becomes low.

### SUMMARY OF THE INVENTION

The present invention has been made in consideration of the above-mentioned facts, and the object of the invention is to acquire an image detection apparatus capable of enhancing the S/N ratio of an output signal at the time of reading electric charges.

An aspect of the present invention is an image detection apparatus. The image detection apparatus includes: a conversion unit that converts an emitted radiation ray or an electromagnetic wave to an electric charge; a group of pixel units, each of the pixel units including a storage capacitor that stores an electric charge converted by the conversion unit and a switching component connected to the storage capacitor; a plurality of signal detection components, each of the signal detection components detecting a difference between electric currents flowing through a pair of lines connected to input terminals thereof; a plurality of data lines that respectively connect the switching components of the pixel units to first input terminals of the signal detection components so that, when a switching component is turned on, the storage capacitor connected thereto conducts to an input terminal of the signal detection components connected thereto; and a plurality of storage capacitor lines that are separate from each other and that connect the storage capacitors of the pixel units of the pixel group to second input terminals of the signal detection components corresponding to the respective pixel units.

### BRIEF DESCRIPTION OF THE DRAWINGS

FIG. 1A is a schematic view to show an example of an image detection apparatus according to the present invention.

FIG. 1B is a schematic view to show the flow of electric currents in data wiring and storage capacitor wiring.

FIG. 2 is a general construction diagram of a radiation image pick-up apparatus according to the present invention.

FIG. 3 is a schematic configuration diagram of a radiation detection panel.

FIG. 4 is a plan view of a region in which a single pixel unit of the radiation detection panel is formed.

FIG. 5 is a section view along a line V-V in FIG. 4.

FIG. 6 is a schematic view to show the arrangement of storage capacitor wiring and the like in the radiation detection panel according to an embodiment of the present invention.

FIG. 7 is a schematic view to show an enhancement in the S/N ratio of the radiation detection panel.

FIG. 8 is a schematic configuration diagram of a radiation detection panel of a direct conversion type in a related art.

FIG. 9 is a schematic view to show the arrangement of storage capacitor wiring and the like in the radiation detection panel in a related art.

### DETAILED DESCRIPTION OF THE INVENTION

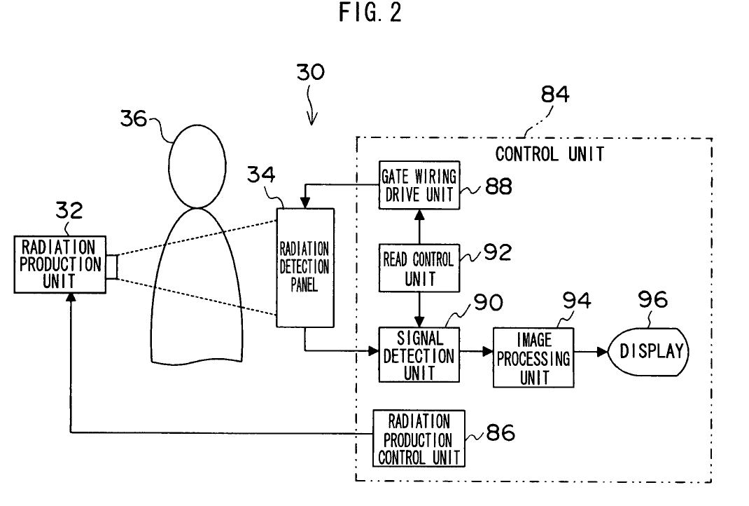

One example of an embodiment of the present invention will be described with reference to the drawings. A radiation image pick-up apparatus 30 according to this embodiment is shown in FIG. 2. The radiation image pick-up apparatus 30 has a radiation production unit 32 that produces a radiation (for example, X ray) and a radiation detection panel 34 arranged apart from the radiation production unit 32. An image pick-up position at which a subject 36 is located at the time of picking-up the image of the subject 36 is arranged between the radiation production unit 32 and the radiation detection panel 34. A radiation, which is emitted from the radiation production unit 32 and is made to pass through the subject 36 located at the image picking-up position to carry image information, is applied to the radiation detection panel 34. Here, the radiation image pick-up apparatus 30 corresponds to an image detection apparatus in a first aspect and the like.

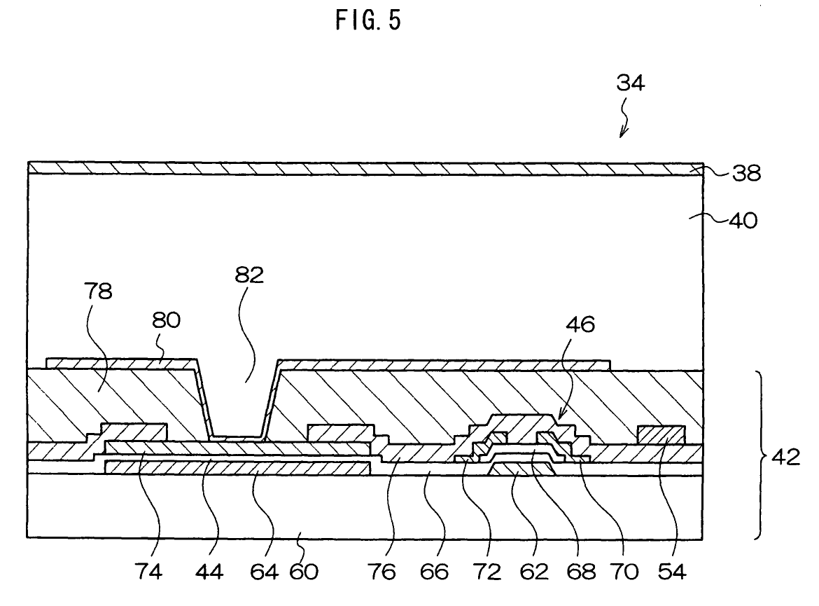

As shown in FIG. 5, the radiation detection panel 34 is configured by laminating a TFT active matrix substrate 42, a photoelectric conversion layer 40 having electromagnetic wave conductivity, and a bias electrode 38 connected to a high-voltage power source in sequence. The photoelectric conversion layer 40 is made of, for example, amorphous selenium (a-Se), the main component of which is selenium (for example, the rate of content is 50% or more). When a radiation is applied to the photoelectric conversion layer 40, the applied radiation is converted to the electric charges by generating electric charges (pairs of electron and positive hole) of a quantity corresponding to the quantity of applied radiation therein. With this, the image information carried by the applied radiation is converted to charge information. Here, the photoelectric conversion layer 40 corresponds to a conversion unit of the present invention.

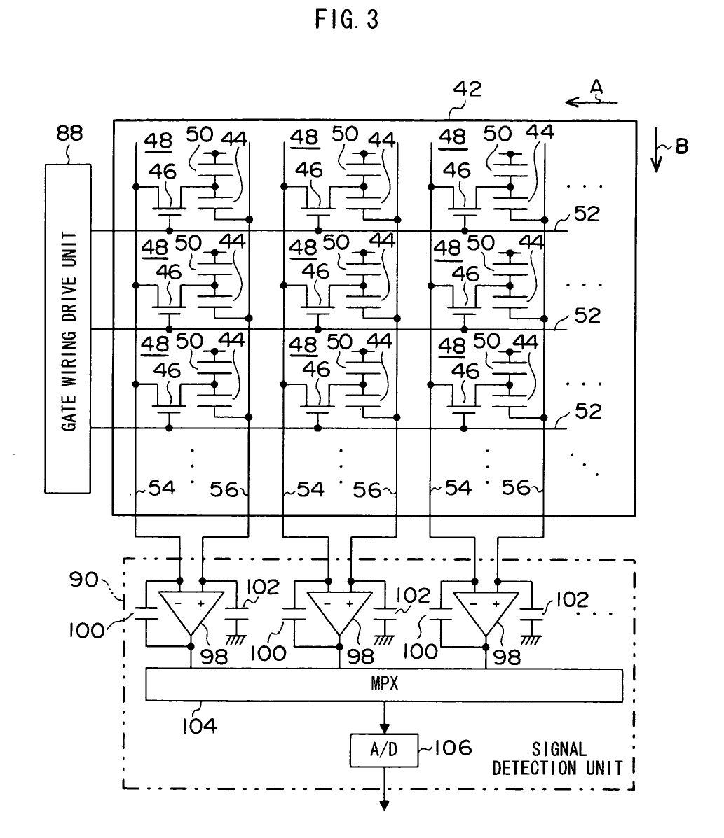

Moreover, as shown in FIG. 3, a number of pixel units 48, each of which includes a storage capacitor 44 that stores electric charges produced by the photoelectric conversion layer 40 and a TFT 46 that reads the electric charges stored in the storage capacitor 44 (here, in FIG. 3, the bias electrode 38 and the photoelectric conversion layer 40, which correspond to each pixel unit 48, are schematically shown as a photoelectric conversion unit 50), are arranged in the shape of a matrix on the TFT active matrix substrate 42. Further, plural gate wiring 52, which are extended along a direction shown by an arrow A in FIG. 3 (which corresponds to a first direction of a third aspect) and turns on and off the TFTs 46 of the individual pixel units 48, plural data wiring 54, which are extended along a direction shown by an arrow B perpendicular to the direction shown by the arrow A in FIG. 3 and reads the stored electric charges from the storage capacitors 44 via the turned-on TFTs 46, and plural storage capacitor wiring 56, which are extended along the direction shown by the arrow B in FIG. 3 (which corresponds to a second direction of the third aspect) and are connected to the storage capacitors 44 of the individual pixel units 48, are also formed on the TFT active matrix substrate 42. Here, the gate wiring 52 correspond to the control signal wiring of the third aspect.

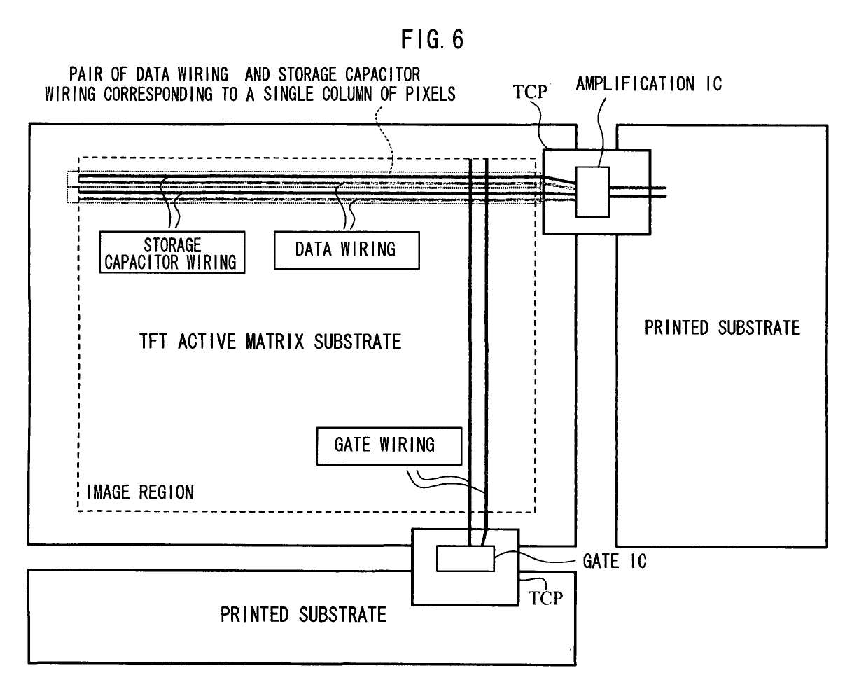

In this regard, the gate wiring 52 are formed in the same number as the number of the rows of the pixel units 48 when a number of pixel units 48 arranged in the shape of a matrix on the TFT active matrix substrate 42 are divided into the rows of the pixel units composed of the plural pixel units 48 arranged along the direction shown by the arrow A in FIG. 3, and the individual gate wiring 52 are connected to (the individual pixel units 48 that configures) the rows of the pixel units different from each other. Moreover, the data wiring 54 and the storage capacitor wiring 56 are formed in the same number as the number of the columns of the pixel units 48 when a number of pixel units 48 arranged in the shape of a matrix on the TFT active matrix substrate 42 are divided into the columns of the pixel units composed of the plural pixel units 48 arranged along the direction shown by the arrow B in FIG. 3 (see also FIG. 6 as an example), and the plural data wiring 54 are connected to (the individual pixel units 48 that configures) the columns of the pixel units different from each other, and the storage capacitor wiring 56 are also connected to (the individual pixel units 48 that configures) the rows of the pixel units different from each other. Still further, in this embodiment, the wiring resistances of the individual data wiring 54 and the individual storage capacitor wiring 56 are made nearly equal to each other.

In this regard, among a number of pixel units 48 formed on the TFT active matrix substrate 42, the plural pixel units 48 (individual pixel units 48 configuring a single row of the pixel units) connected to the same gate wiring 52 correspond to a group of pixels of the present invention. The storage capacitor 44 corresponds to a storage capacitor of the present invention, and the TFT 46 corresponds to a switching component of the present invention, and the data wiring 54 corresponds to data wiring of the present invention, and the storage capacitor wiring 56 corresponds to storage capacitor wiring of the present invention. Moreover, the TFT active matrix substrate 42 corresponds to a substrate of the third aspect.

The individual pixel units 48 of the TFT active matrix substrate 42 are formed respectively on a glass substrate 60 as a support substrate, shown in FIG. 5. Here, for example, an alkali-free glass (for example, #1737 made by Corning Incorporated) can be used as the glass substrate 60. Moreover, as shown in FIG. 5, in each of the pixel units 48, a gate electrode 62, a storage capacitor lower electrode 64, a gate insulation film 66, a semiconductor layer 68, a source electrode 70, a drain electrode 72, a storage capacitor upper electrode 74, an insulation protection film 76, an insulation protection film 78, and an electric charge collection electrode 80 are formed on the glass substrate 60, respectively. Among them, the gate electrode 62, the gate insulation film 66, the source electrode 70, the drain electrode 72, and the semiconductor layer 68 configure the above-mentioned TFT 46, whereas the storage capacitor lower electrode 64, the gate insulation film 66, and the storage capacitor upper electrode 74 configure the above-mentioned storage capacitor 44.

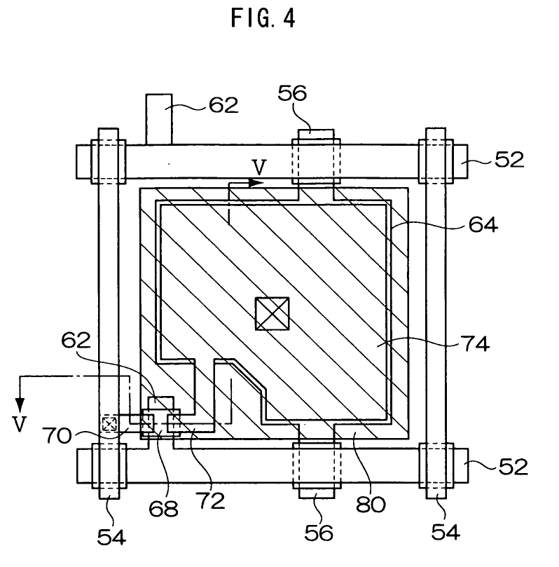

The gate wiring 52 is formed in a metal layer in which the gate electrode 62 of the TFT 46 is also formed, and as shown in FIG. 4, the gate electrode 62 of the TFT 46 is connected to the gate wiring 52. Moreover, the source electrode 70 of the TFT 46 is connected to the data wiring 54 via a contact hole, whereas the drain electrode 72 of the TFT 46 is connected to the storage capacitor upper electrode 74. Further, the storage capacitor wiring 56 extended along the direction shown by the arrow B in FIG. 3 are formed in the metal layer in which the storage capacitor lower electrode 64 is also formed, and as shown in FIG. 4, the storage capacitor lower electrode 64 is connected to the storage capacitor wiring 56. In this regard, the TFT active matrix substrate 42 has the plural columns of pixel units formed thereon. Each column of pixel units is configured by plural pixel units 48 arranged along the direction shown by the arrow B in FIG. 3. However, as shown also in FIG. 3, the individual storage capacitor wiring 56 are connected to only (the storage capacitor lower electrodes 64 of) the storage capacitors 44 of the pixel units 48 configuring the columns of the pixels different from each other, and the individual storage capacitor wiring 56 are electrically separated from each other.

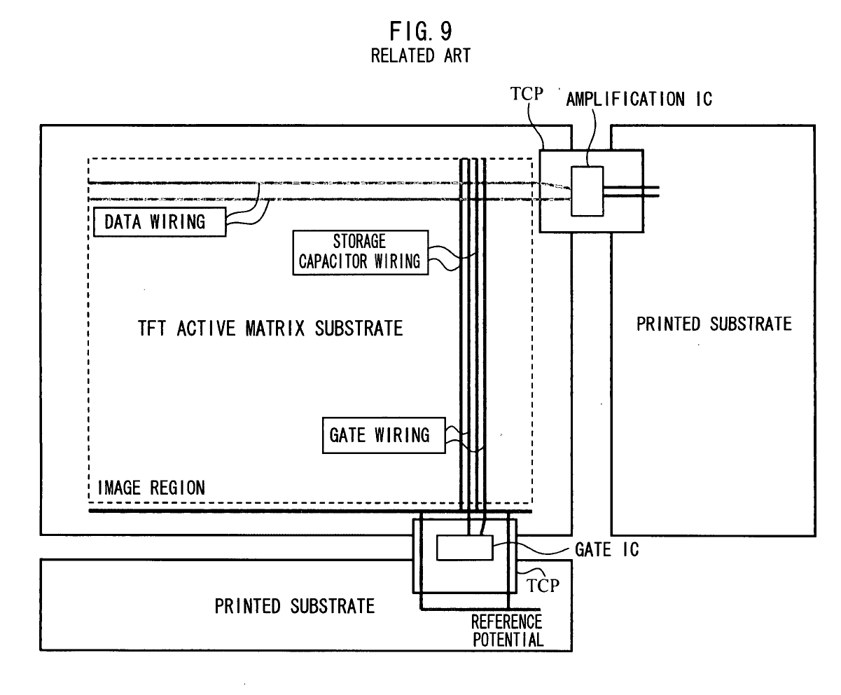

In other words, the individual storage capacitor wiring 56, as is clear when FIG. 6 is compared with FIG. 9 described above, are not connected to each other via connection wiring formed on the TFT active matrix substrate 42 (or outside the substrate 42) but are connected directly to an amplifier IC (plural operational amplifiers 98 or the like to be described later are built in this amplifier IC) formed on a TCP (ditto for the data wiring). The individual storage capacitor wiring 56 are electrically separated and insulated from each other.

Moreover, the gate insulation film 66 is made of SiNx, SiOx, or the like and is formed so as to cover the gate electrode 62, the gate wiring 52, the storage capacitor lower electrode 64, and the storage capacitor wiring 56. In a portion covering the gate electrode 62, the gate insulation film 66 acts as a gate insulation film in the TFT 46, whereas in a portion covering the storage capacitor lower electrode 64, the gate insulation film 66 acts as a dielectric layer in the storage capacitor 44. Thus, a region in which the storage capacitor lower electrode 64 and the storage capacitor upper electrode 74 overlap each other functions as the storage capacitor 44.

Further, the semiconductor layer 68 functions as a channel part of the TFT 46, and the source electrode 70 and the drain electrode 72 are conducted via the semiconductor layer 68. Still further, the insulation protection film 76 is formed on the almost entire face of a region (almost entire region) corresponding to the single pixel unit 48 on the glass substrate 60, thereby realizing the protection and the electrically insulating separation of the drain electrode 72 and the source electrode 70. Still further, a contact hole 82 is formed in a portion opposite to the storage capacitor lower electrode 64 of the insulation protection film 76.

Still further, the electric charge collection electrode 80 is made of an amorphous transparent conductive oxide film and is formed so as to bury the contact hole 82 and is formed above the source electrode 70, the drain electrode 72, and the storage capacitor upper electrode 74. The electric charge collection electrode 80 and the photoelectric conversion layer 40 are conducted, and the electric charges produced in the photoelectric conversion layer 40 are collected by the electric charge collection electrode 80. The insulation protection film 78 is made of acrylic resin having photosensitivity and realizes the electrically insulating separation of the TFT 46 from the other parts. The insulation protection film 78 has the contact hole 82 passed therethrough, and the electric charge collection electrode 80 is connected to the storage capacitor upper electrode 74 via the contact hole 82.

Still further, as shown in FIG. 2, the radiation image pick-up apparatus 30 has a control unit 84 configured of a microcomputer and various electric circuits, and the radiation production unit 32 and the radiation detection panel 34 are connected to the control unit 84. That is, the control unit 84 has: a radiation production control unit 86 that is connected to the radiation production unit 32 and that controls the production of the radiation produced by the radiation production unit 32; a gate wiring drive unit 88 that is connected to the individual gate wiring 52 of the radiation detection panel 34 and that turns on and off the TFTs 46 of the respective pixel units 48 via the gate wiring 52; a signal detection unit 90 that is connected to the individual data wiring 54 and the individual storage capacitor wiring 56 of the radiation detection panel 34 and that performs a specified signal processing such as an amplification processing and an AID conversion processing to a signal outputted from the storage capacitors 44 of the respective pixel units 48 of the radiation detection panel 34 via the data wiring 54; a read control unit 92 that is connected to the gate wiring drive unit 88 and the signal detection unit 90 and that controls the operation of the gate wiring drive unit 88 and the signal detection unit 90 at the time of reading the electric charges from the radiation detection panel 34; an image processing unit 94 that is connected to the signal detection unit 90 and that performs a specified image processing (various correction processings such as an offset correction processing and a shading correction processing) to an image expressed by an image signal, which has been subjected to the specified processing and outputted from the signal detection unit 90; and a display 96 that displays the image signal, which has been subjected to the specified image processing by the image processing unit 94, as an image.

As shown in FIG. 3, the signal detection unit 90 has the operational amplifiers 98 of the same number as the number of columns of pixel units (the number of the data wiring 54 and the number of the storage capacitor wiring 56) formed on the TFT active matrix substrate 42, and the individual data wiring 54 formed on the radiation detection panel 34 are connected to the inverted input terminals of the operational amplifiers 98 different from each other. Moreover, the individual storage capacitor wiring 56 formed on the radiation detection panel 34 are also connected to the non-inverted input terminals of the operational amplifiers 98 different from each other, in more detail, to the non-inverted input terminals of the same operational amplifiers 98 as the data wiring 54 connected to the same column of pixel units as their own wiring (data wiring 54 pairing with its own wiring).

Each of the operational amplifiers 98 has its output terminal connected to the input terminal of a multiplexer (MPX) 104 and has its inverted input terminal connected to its output terminal via a capacitor 100 and has its non-inverted input terminal grounded via a capacitor 102. With this, each of the operational amplifiers 98 functions as a charge amplifier that detects a difference between an electric current flowing through the data wiring 54 connected to the inverted input terminal and an electric current flowing through the storage capacitor wiring 56 connected to the non-inverted input terminal (electric current responsive to the quantity of electric charges stored in the storage capacitor 44) and that outputs a signal of level corresponding to the detected difference. Here, the operational amplifier 98 functioning as the charge amplifier and the capacitors 100, 102 correspond to a signal detection component according to the invention. Moreover, the output terminal of the MPX 104 is connected to the input terminal of an A/D converter 106, and the output terminal of the A/D converter 106 is connected to the image processing unit 94.

In this regard, in place of a configuration in which one MPX 104 and one A/D converter 106 are disposed as described above, it is also recommended to employ a configuration in which the MPX 104 is not included and in which the A/D converters 106 of the same number as the number of the operational amplifiers (charge amplifiers) 98 are connected to the output terminals of the operational amplifiers (charge amplifiers) 98 different from each other.

Next, the operation of this embodiment will be described. When the subject 36 is picked up (shot) by the radiation image pick-up apparatus 30, the radiation production control unit 86 of the control unit 84 controls the emission of the radiation from the radiation production unit 32 in such a way that the radiation emitted from the radiation production unit 32 is applied to the subject 36 in a state where the subject 36 is located at the position where an image of the subject 36 is picked up and where a high voltage is applied to the bias electrode 38 of the radiation detection panel 34. The radiation having been emitted from the radiation production unit 32 and passed through the subject 36 and thereby carrying image information is applied to the radiation detection panel 34. At this time, the high voltage is applied to the bias electrode 38 of the radiation detection panel 34, so that in the photoelectric conversion layer 40 of the radiation detection panel 34, there are produced electric charges (pairs of electrons and positive holes) of the quantity of electric charges responsive to the quantity of radiation applied to respective positions on the light receiving face of the radiation detection panel 34.

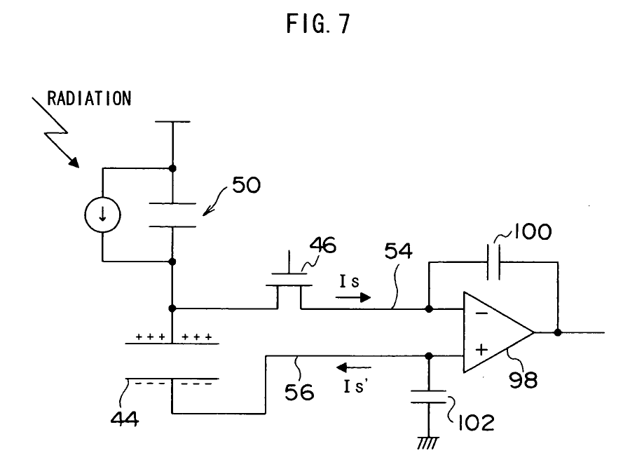

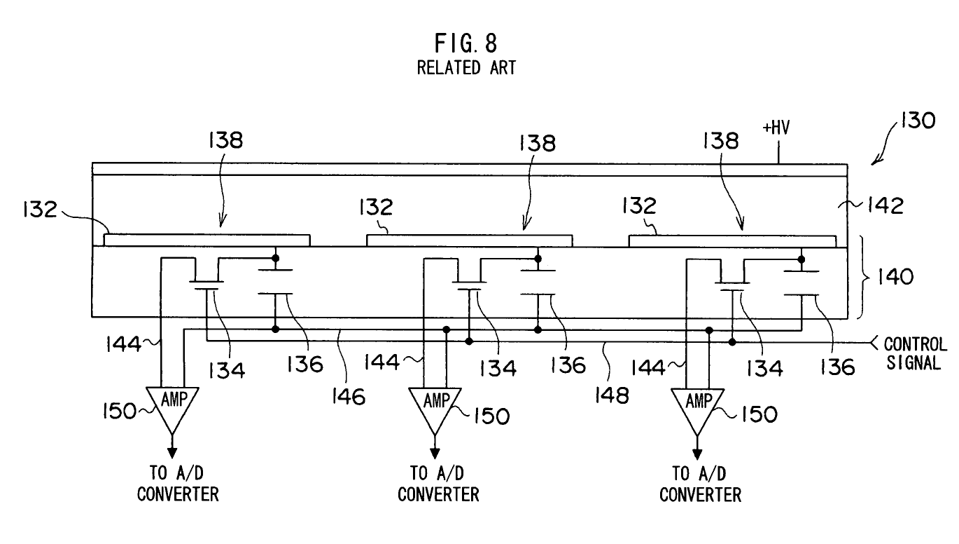

The photoelectric conversion layer 40 and the storage capacitor 44 are electrically connected in series to each other via the electric charge collection electrode 80, so that as shown also in FIG. 7 by way of example, in the each of the pixel units 48 formed on the radiation detection panel 34, positive holes (or electrons) produced in the photoelectric conversion layer 40 move to the storage capacitor upper electrode 74 and hence electrons (or positive holes) balancing the positive holes (or the electrons) having moved to the storage capacitor upper electrode 74 collect in the storage capacitor lower electrode 64 opposite to the storage capacitor upper electrode 74, whereby the electric charges of the quantity of electric charges produced in the photoelectric conversion layer 40, that is, the electric charges of the quantity of electric charges responsive to the quantity of applied radiation are stored in the storage capacitor 44 of each of the pixel units 48.

Subsequently, the electric charges are read from the storage capacitor 44 of each of the pixel units 48 of the radiation detection panel 34. That is, the read control unit 92 of the control unit 84 controls the gate wiring drive unit 88 in such a way that the an ON signal for turning on the TFTs 46 of the pixel units 48 is supplied to a single line of gate wiring 52 for a specified time. With this, in the individual pixel units 48 connected to the single line of gate wiring 52 having the ON signal supplied thereto, the TFTs 46 are turned on respectively. Thus, in each of pixel units 48, the positive holes (or electrons) held in the storage capacitor upper electrode 74 of the storage capacitor 44 flow through the data wiring 54 as a signal current Is (see FIG. 7) and the electrons (or positive holes) held in the storage capacitor lower electrode 64 of the storage capacitor 44 flow through the storage capacitor wiring 56 as a signal current Is′ that is nearly equal to the signal current Is in amplitude and is opposite to the signal current Is in the direction of flow (see FIG. 7).

Here, in this embodiment, the individual storage capacitor wiring 56 are electrically separated from each other and are connected to the non-inverted input terminals of the operational amplifiers 98 different from each other and that the individual operational amplifiers 98 function as the charge amplifiers each of which outputs a signal of level responsive to the difference between the electric current (signal current Is) flowing through the data wiring 54 connected to the inverted input terminal and the electric current (signal current Is′) flowing through the storage capacitor wiring 56 connected to the non-inverted input terminal. Accordingly, the difference between the electric current flowing Is through the data wiring 54 and the electric current Is′ flowing through the storage capacitor wiring 56 is Is−(−Is′)≈2Is, that is, the level of a signal component in the output signal from each of the individual operational amplifiers 98 becomes nearly two times a level in the related art. On the other hand, when a random noise is superimposed on one of the signal current Is flowing through the storage data wiring 54 and the signal current Is′ flowing through the storage capacitor wiring 56, the level of the noise component included in the output signal from the operational amplifier 98 becomes nearly \sqrt{2} times a level in the related art. Thus, the S/N ratio of the output signal from each of the operational amplifiers 98 (charge amplifier) can be enhanced nearly by a factor of \sqrt{2}.

Still further, in this embodiment, the wiring resistances of the individual data wiring 54 and the individual storage capacitor wiring 56 are nearly equal to each other, so that the amplitudes of the signal current Is and the signal current Is′, which respectively flow through the data wiring 54 and the storage capacitor wiring 56 that make a pair (the data wiring 54 and the storage capacitor wiring 56 that are connected to the same line of pixel units) are nearly equal to each other, and even when noises of the same polarity and the same amplitude (common mode noises) are superimposed at the same timing on the signal current Is and the signal current Is′ that respectively flow through the data wiring 54 and the storage capacitor wiring 56 that make a pair, the level of the noise component superimposed on the signal current Is is nearly equal to the level of the noise component superimposed on the signal current Is′, and the difference between the signal current Is and the signal current Is′ can be detected by the operational amplifier 98 (charge amplifier). Thus, the noises that are of the same polarity and the same amplitude and that are superimposed at the same timing on each of the signal current Is and the signal current Is′ can be canceled on the output signal from the operational amplifier 98 (charge amplifier). With this, even when the noises of the same polarity and amplitude are superimposed at the same timing on the signal current Is and signal current Is′ that flow respectively through the data wiring 54 and the storage capacitor wiring 56 that make a pair, it is also possible to avoid the S/N ratio of the output signal from the operational amplifier 98 (charge amplifier) from being deteriorated. Thus, a signal of high S/N ratio is outputted as an output signal expressing the quantity of stored electric charges in the storage capacitor 44 from each of the operational amplifiers 98 (charge amplifiers).

Still further, the read control unit 92 of the control unit 84 controls the MPX 104 in such a way that the output signals from the individual operational amplifiers 98 (charge amplifiers) are selected in sequence by the MPX 104 and are outputted in sequence to the A/D converter 106 within a period in which the ON signal is supplied to the single row of gate wiring 52. With this, the output signals, each of which expresses the quantity of stored electric charges in the storage capacitor 44 of each of the individual pixel units 48 connected to the gate wiring 52 having the ON signal supplied thereto, are inputted in sequence to the A/D converter 106 via the MPX 104, and image signals (digital data), each of which expresses the quantity of electric charges stored in the storage capacitor 44 of each of the individual pixel units 48 connected to the gate wiring 52 having the ON signal supplied thereto, are outputted in sequence from the A/D converter 106.

The read control unit 92 of the control unit 84 repeatedly controls the gate wiring drive unit 88 in such a way that every time all of the image signals corresponding to the individual pixel units 48 connected to the gate wiring 52 having the ON signal supplied thereto are outputted from the A/D converter 106, the gate wiring 52 to which the ON signal is to be supplied is switched, and repeatedly controls the MPX 104 in such a way that the output signals from the individual operational amplifiers 98 (charge amplifiers) are selected in sequence by the MPX 104 and are outputted in sequence to the A/D converter 106 within a period in which the ON signal is supplied to the single row of gate wiring 52. With this, the image signals corresponding to all of the pixel units 48 of the radiation detection panel 34, that is, the image signals expressing the image information carried by the radiation having passed through the subject 36 can be acquired, and the image signals are subjected to the image processing performed by the image processing unit 94 and are displayed as an image on the display 96.

As described above, in this embodiment, the individual storage capacitor wiring 56 are electrically separated from each other and are connected to the non-inverted input terminals of the operational amplifiers 98 different from each other, respectively, and that the individual operational amplifiers 98 function as the charge amplifiers each of which outputs a signal of level responsive to the difference between the electric current (signal current Is) flowing through the data wiring 54 connected to the inverted input terminal thereof and the electric current (signal current Is′) flowing through the storage capacitor wiring 56 connected to the non-inverted input terminal thereof Thus, it is possible to make each of the operational amplifiers (charge amplifiers) 98 output a signal of high S/N ratio as a signal to express the quantity of electric charges stored in the storage capacitor 44 of each of the pixel units 48 and hence to enhance the quality of an image displayed on the display 96.

In this regard, a case has been described above in which the wiring resistances of the plural date wiring 54 and the plural storage capacitor wiring 56 that are formed in the radiation detection panel 34 are nearly equal to each other. However, it is preferable that all of the wiring resistances of the plural data wiring 54 and the plural storage capacitor wiring 56 are nearly equal to each other, but the invention is not limited to this. For example, if the wiring resistances of the data wiring 54 and the storage capacitor wiring 56 (the data wiring 54 and the storage capacitor wiring 56 that are connected to the same column of pixel units) that make a pair are nearly equal to each other, even when noises of the same polarity and the same amplitude (common noise) are superimposed at the same timing on the signal current Is and the signal current Is′ that flow respectively through the data wiring 54 and the storage capacitor wiring 56 that make a pair, the superimposed noises can be almost cancelled, so that the wiring resistances of the data wiring 54 and the storage capacitor wiring 56 that are connected to the different rows of pixel units may be different from each other. Moreover, when the common noises can be reduced by the other means, the wiring resistances of the data wiring 54 and the storage capacitor wiring 56 that make a pair may be different from each other to some extent.

Further, the charge amplifier configured in such a way that the inverted input terminal of the operational amplifier 98 is connected to the output terminal thereof via the capacitor 100 and that the non-inverted input terminal of the operational amplifier 98 is grounded via the capacitor 102 has been described above as the example of a signal detection component of the present invention, but the present invention is not limited to this. The signal detection component of the present invention may be, for example, an I/V amplifier (current—voltage conversion amplifier) configured in such a way that the inverted input terminal of an operational amplifier is connected to an output terminal thereof via a resistor and that the non-inverted input terminal of the operational amplifier is grounded via a resistor.

Still further, an aspect has been described above in which the gates of the TFTs 46 of the plural pixel units 48 arranged along the direction shown by the arrow A in FIG. 3 (plural pixel units configuring a group of pixels of the present invention) are connected to the same row of gate wiring 52 and in which the TFTs 46 of the plural pixel units 48 are turned on at the same timing, but the present invention in not limited to this. The present invention can be applied also to an aspect in which the switching components of the individual pixel units configuring a group of pixels of the present invention are turned on in sequence to produce a time-series signal.

Still further, the photoelectric conversion layer 40 that directly converts the applied radiation to the electric charges has been described as an example of a conversion unit of the present invention, but the present invention is not limited to this. The conversion unit of the present invention may have a configuration in which an applied radiation is once converted to an electromagnetic wave (for example, visible light or the like) and then the converted electromagnetic wave is converted to the electric charges (indirect conversion type). Moreover, a configuration has been described above in which the photoelectric conversion layer 40 as the conversion unit of the present invention is formed on the TFT active matrix substrate 42, but the conversion unit of the present invention may be a part separate from a substrate having plural pixel units arranged thereon, each of the plural pixel units having a storage capacitor and a switching component formed thereon.

Still further, the radiation detection panel 34 of a configuration in which a number of pixel units 48 (TFTs 46 and the storage capacitors 44) are arranged in the shape of a matrix (two-dimensionally) has been described as an example of an electromagnetic wave detection panel of the present invention, but the present invention is not limited to this. The electromagnetic wave detection panel of the present invention may have a configuration in which plural pixel units are arranged in a single column (one-dimensionally).

Still further, an X ray has been described above as one example of the radiation converted to the electric charges by the conversion layer of the present invention, but the present invention is not limited to this. Other radiation, for example, an electron beam or an a ray may be employed or an electromagnetic wave of an arbitrary wavelength region, for example, visible light, ultra-violet ray, or infrared ray may be employed, if the electromagnetic wave can be absorbed by the conversion unit and converted to electric charges and the electric charges can be stored in the storage capacitors.

A first aspect of the present invention is an image detection apparatus including: a conversion unit that converts an applied radiation or electromagnetic wave to an electric charge; a group of pixels composed of a plurality of pixel units each of which includes a storage capacitor for storing the electric charge converted by the conversion unit and a switching component connected to one end of the storage capacitor; a plurality of signal detection components each of which detects a difference between electric currents flowing through a pair of wiring connected to input terminals thereof; a plurality of data wiring each of which connects the switching components of the pixel units different from each other of the group of pixels to one input terminals of signal detection components different from each other of the plurality of signal detection components in such a way that when each of the switching components is turned on, one end of each of the storage capacitors conducts to an input terminal of each of the signal detection components; and a plurality of storage capacitor wiring that are separated from each other and that connect other ends of the storage capacitors of the different pixels parts of the group of pixels to other input terminals of the signal detection components corresponding to the respective pixel units.

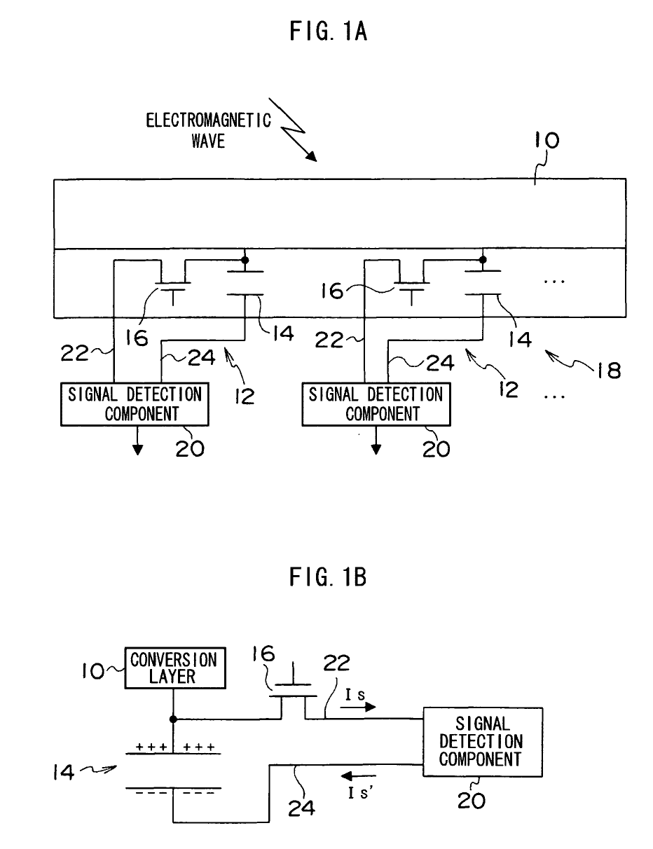

The first aspect of the present invention, as shown also in FIG. 1A by way of example, includes: a conversion unit 10 that converts an applied radiation or electromagnetic wave to an electric charge; and a group of pixels 18 composed of a plurality of pixel units 12 each of which includes a storage capacitor 14 for storing the electric charge converted by the conversion unit 10 and a switching component 16 connected to one end of the storage capacitor 14, and the radiation or the electromagnetic wave applied to the conversion unit 10 is converted to the electric charge by the conversion unit 10 and the converted electric charge is stored in the respective storage capacitors 14 of the individual pixel units 12.

The first aspect further includes a plurality of signal detection components 20 each of which detects a difference between electric currents flowing through a pair of wiring connected to input terminals thereof, and still further includes: a plurality of data wiring 22 each of which connects the switching components 16 of the pixel units 12 different from each other of the group of pixels 18 to one input terminals of signal detection components 20 different from each other of the plurality of signal detection components 20 in such a way that when each of the switching components 16 is turned on, one end of each of the storage capacitors 14 conducts to an input terminal of each of the signal detection components 20; and a plurality of storage capacitor wiring 24 that are separated from each other and that connect other ends of the storage capacitors 14 of the different pixels parts 12 of the group of pixels 18 to other input terminals of the signal detection components 20 corresponding to the respective pixel units 12.

Here, in a state where the electric charges converted by the conversion unit 10 are stored in each of the storage capacitors 14 of the individual pixel units 12, as shown in FIG. 1B by way of example, the electric charges having different polarities and the same quantity of electric charges are held on one end side and the other end side of the storage capacitor 14. When the switching component 16 is turned on in this state, the electric charges held on the one end side (side to which the switching component 16 is connected) of the storage capacitor 14 flow through the data wiring 22 as a signal current Is, which then varies the quantity of electric charges held on the one end side of the storage capacitor 14. Then, this variation in the quantity of electric charges varies the quantity of electric charges held on the other end side of the storage capacitor 14. Thus, as a result, a signal current Is′ that is nearly equal in amplitude to the signal current Is and that is opposite in direction to the signal current Is flows through the storage capacitor wiring 24 (as will be described later, when the wiring resistance of the data wiring 22 is equal to the wiring resistance of the storage capacitor wiring 24, the amplitude of the signal current Is is equal to the amplitude of the signal current Is′). In the configuration of the related art, the storage capacitor wiring connected to the storage capacitors of the individual pixel units are connected to each other, so that the signal current Is′ is diffused by the storage capacitor wiring connected to the entire region of the device and the GND wiring of the device (grounding wiring) and hence only the signal current Is is substantially amplified and outputted as an output signal.

The first aspect is configured in such a way that the other ends of the storage capacitors of the pixel units different from each other are connected to the input terminals of the signal detection components corresponding to the respective pixel units by the plurality of storage capacitor wiring separated from each other, and that each of the signal detection components detects a difference between electric currents flowing through a pair of wiring connected to the input terminals thereof, so that the difference between the electric current Is flowing through the data wiring and the electric current Is′ flowing through the storage capacitor wiring becomes Is−(−Is′)≈2Is and hence the level of a signal component in an output signal from the signal detection component becomes two times a level in the related art. Moreover, when a noise is superimposed on one of the electric current Is flowing through the data wiring and the electric current Is′ flowing through the storage capacitor wiring, the level of a noise component in the output signal from the signal detection component becomes nearly \sqrt{2} time a level in the related art. Thus, the level of the signal component becomes two times the level in the related art, whereas the level of the noise component becomes nearly \sqrt{2} time a level in the related art, so that the S/N ratio of the output signal is enhanced to nearly \sqrt{2} time a level in the related art.

Further, when noises of the same polarity and the same amplitude (this kind of noise is also referred to as a common noise) are superimposed at the same timing on the electric current Is flowing through the data wiring and the electric current Is′ flowing through the storage capacitor wiring, the difference between the electric current Is and the electric current Is′ is detected by the signal detection component and hence the noises superimposed in the same way respectively on the electric current Is and the electric current Is′ can be nearly canceled, so that when this kind of noises are superimposed, the S/N ratio of the output signal can be also avoided from being deteriorated. Thus, according to the first aspect, the S/N ratio of the output signal at the time of reading the electric charges can be enhanced.

A second mode may be of a construction in which: in the image detection apparatus of the first mode, the group of pixels are arranged plurally; and the switching components of the individual pixel units are turned on at timings different from each other for each of the group of pixels. In this case, it is preferable that for example, the plurality of data wiring are connected to the respective switching components of the pixel units different from each other of the plurality of pixel units constructing each of the group of pixels, and that the plurality of storage capacitor wiring are connected to the respective storage capacitors of the pixel units different from each other of the plurality of pixel units constructing each of the group of pixels. In the above-mentioned construction, the individual storage capacitor wiring are connected to the storage capacitors of the plurality of pixel units, but the plurality of pixel units the storage capacitors of which are connected to the same storage capacitor wiring are pixel units the switching components of which are turned on at timings different from each other, so that the fact that the storage capacitors of the plurality of pixel units are connected to the individual storage capacitor wiring does not have a bad effect on the deterioration of the S/N ratio of the output signal. Since the storage capacitors of the plurality of pixel units are connected to the individual storage capacitor wiring, it is possible to prevent an increase in the number of storage capacitor wiring and hence to realize a simplified construction.

A third aspect is the image detection apparatus of the second aspect, wherein when the plurality of pixel units configuring each of the plurality of groups of pixels are arranged along a first direction on a substrate and the plurality of groups of pixels are arranged along a second direction perpendicular to the first direction on the substrate, the pixel units of the same group of pixels are arranged along the first direction on the substrate whereas the pixel units of the different groups of pixels (pixel units the switching components of which are turned on at timings different from each other) are arranged along the second direction on the substrate. For example, a plurality of control signal wiring for supplying a control signal to each of the switching components of the respective pixel units of the different groups of pixels of the plurality of groups of pixels are formed along the first direction on the substrate, and the plurality of data wiring and the plurality of storage capacitor wiring are arranged along the second direction on the substrate, respectively.

With this, the configuration that: the plurality of data wiring are connected to the respective switching components of the pixel units different from each other of the plurality of pixel units configuring the individual groups of pixels; the plurality of storage capacitor wiring are connected to the storage capacitors of the pixel units different from each other of the plurality of pixel units configuring the individual groups of pixels; and the switching components are turned on for the individual groups of pixels can be realized without complicating the respective wiring formed on the substrate. Thus, it is possible to realize the facilitation of the design work of determining the arrangement of the respective wiring on the substrate.

A fourth aspect is the image detection apparatus of any one of the first to third aspects, wherein the plurality of data wiring and the plurality of storage capacitor wiring are nearly equal to each other in a wiring resistance, for example, at least for a unit of the data wiring and the storage capacitor wiring that are respectively connected to the input terminal of a same signal detection component. With this, when noises of the same polarity and the same amplitude (common noise) are superimposed at the same timing on the electric currents (signal current Is and signal current Is′) that flow respectively through the data wiring and the storage capacitor wiring that are respectively connected to the input terminals of the same signal detection component, the levels of the noise components in the respective electric currents are equal to each other (the magnitudes of the electric currents that flow respectively through the data wiring and the storage capacitor wiring that are respectively connected to the input terminals of the same signal detection component are also equal to each other). Thus, when the noises of the same polarity and the same amplitude are superimposed at the same timing on the electric currents that flow respectively through the data wiring and the storage capacitor wiring that are respectively connected to the input terminals of the same signal detection component, the superimposed noises can be canceled correctly and hence the S/N ratio of the output signal can be further increased.

A fifth aspect is the image detection apparatus of any one of the first to fourth aspects, wherein the signal detection component is, for example, a charge amplifier or a current voltage amplifier.

As described above, the present invention is configured in the following manner: that is, the plurality of signal detection components, each of which detects the difference between the electric currents that flow respectively through the pair of wiring connected to input terminals thereof, are disposed; and in order to bring one end of each of the storage capacitors of the plurality of pixel units, each of which includes the storage capacitor for storing the electric charges and the switching component connected to the one end of the storage capacitor, into conduction to each of the input terminals of the signal detection components different from each other when each of the switching components is turned on, the switching components of the pixel units different from each other are connected to the input terminals of the signal detection components different from each other by the plurality of data wiring and the other ends of the storage capacitors of the pixel units different from each other are connected to the input terminals of the signal detection components different from each other by the plurality of storage capacitor wiring separated from each other, Thus, the invention has an excellent effect of increasing the S/N ratio of the output signal at the time of reading the electric charges.

What is claimed is:

1. An image detection apparatus comprising:
a conversion unit that converts an emitted radiation ray or an electromagnetic wave to an electric charge;
a group of pixel units, each of the pixel units including a storage capacitor that stores an electric charge converted by the conversion unit and a switching component connected to the storage capacitor;
a plurality of signal detection components, each of the signal detection components detecting a difference between electric currents flowing through a pair of lines connected to input terminals thereof;
a plurality of data lines that respectively connect the switching components of the pixel units to first input terminals of the signal detection components so that, when a switching component is turned on, the storage capacitor connected thereto conducts to an input terminal of the signal detection components connected thereto; and
a plurality of storage capacitor lines that are separate from each other and that connect the storage capacitors of the pixel units of the pixel group to second input terminals of the signal detection components corresponding to the respective pixel units.

2. The image detection apparatus of claim 1, wherein
the group of pixel units are provided as plural groups;
the switching components of the individual pixel units of different groups of pixels are turned on at different times;
each of the plurality of data lines of the plurality of pixel units that form each group of pixels is connected to the switching components of pixel units different to the pixel unit connected thereto; and
each of the plurality of storage capacitor lines of the plurality of pixel units that form each group of pixels is connected to the storage capacitors of pixel units different to the pixel unit connected thereto.

3. The image detection apparatus of claim 2, wherein
the plurality of pixel units that form each of the plurality of groups of pixels are arranged along a first direction on a substrate;
the plurality of groups of pixels are arranged along a second direction perpendicular to the first direction on the substrate;
a plurality of control signal lines, that respectively supply a control signal to the switching component of each pixel unit of different groups of pixel units of the plurality of groups of pixel units, are formed along the first direction on the substrate; and
the plurality of data lines and the plurality of storage capacitor lines are arranged along the second direction on the substrate.

4. The image detection apparatus of claim 1, wherein
the plurality of data lines and the plurality of storage capacitor lines are substantially equal in wiring resistance at least with respect to data lines and storage capacitor lines that are connected to an input terminal of the same signal detection component.

5. The image detection apparatus of claim 1, wherein the signal detection component is a charge amplifier or a current voltage amplifier.
